(19) United States
(12) Patent Application Publication
(10) Pub. No.: US 2025/0327714 A1
(43) Pub. Date: Oct. 23, 2025

(54) MULTI-SEVERITY LEAK DETECTION APPARATUS FOR COMPUTING DEVICE

(71) Applicant: ZT Group Int'l, Inc., Secaucus, NJ (US)

(72) Inventors: Sruti CHIGULLAPALLI, Seattle, WA (US); Paul ANDERSON, Leander, TX (US)

(73) Assignee: ZT Group Int'l, Inc., Secaucus, NJ (US)

(21) Appl. No.: 18/637,992

(22) Filed: Apr. 17, 2024

(51) Int. Cl. G01M 3/32

(52) U.S. Cl. CPC G01M 3/3209

(57) ABSTRACT

The apparatus includes a first tray forming a first trough configured to surround a perimeter of a cooling structure. The first trough includes an interior wall with a plurality of portions configured to abut against the perimeter of the cooling structure and an exterior wall including a plurality of portions spaced apart from the portions of the interior wall. The apparatus also includes a first leak detection sensor that is configured to detect a liquid within the first trough or at one or more levels within the first trough and communicate the detection to a computing device. By detecting the liquid level at a plurality of levels in the first tray and/or by using at least one other tray collecting an overflow of the first tray and having another leak detection sensor, a multi-severity leak detection may be achieved.

### FIELD

This disclosure is directed to leak detection in a liquid-cooled computing device.

### BACKGROUND

Many computing devices include electronic components (e.g., circuits, processors, systems-on-chips (SOCs), or amplifiers) that are liquid-cooled. The electronic components interface with cooling structures (e.g., liquid cooling plates, cooling structures, or leak containment structures comprising multiple cooling structures) that transfer heat generated by the electronic components to a liquid flowing through the cooling structures. In many implementations, there are a plurality of liquid-cooled computing devices within a particular area. For example, a collection of servers (e.g., server farm or server cluster) may include thousands of generally co-located computing devices that are liquid-cooled. When leaks exist in such collections (e.g., seals failing within cooling structures, cracks in cooling structures, inlet/outlet connections leaking, or tubing ruptures), it can be difficult to identify severities of the leaks and prioritize them for mitigation.

### SUMMARY

An apparatus for detecting a leak from a cooling structure and/or associated plumbing components that are installed within a computing device is described herein. The apparatus includes a first tray forming a first trough configured to surround a perimeter of the cooling structure. The first trough includes an interior wall with a plurality of portions configured to abut against the perimeter of the cooling structure and an exterior wall including a plurality of portions spaced apart from the portions of the interior wall. The apparatus also includes a first leak detection sensor disposed within the first trough or on top of the interior wall or the exterior wall of the first trough configured to detect a liquid within the first trough or at one or more levels within the first trough and communicate the detection of the liquid in the first trough to the computing device or another computing device.

A system is also described herein. The system includes a plurality of computing devices where each of the computing devices includes a cooling structure attached to one or more electronic components and an apparatus for detecting a leak from the cooling structure and/or associated plumbing components that are installed in the respective computing device. The apparatus includes a first tray forming a first trough that is configured to surround a perimeter of the cooling structure. The first trough includes an interior wall with a plurality of portions configured to abut against the perimeter of the cooling structure and an exterior wall including a plurality of portions spaced apart from the portions of the interior wall. The apparatus also includes a first leak detection sensor disposed within the first trough or on top of the interior wall or the exterior wall of the first trough configured to detect a liquid within the first trough or at one or more levels within the first trough and communicate the detection of the liquid in the first trough outside of the respective computing device. The system also includes a processor remote to the computing devices configured to receive detections of the liquid from the first leak detection sensors of the computing devices and, responsive to receiving a detection of the liquid from a first leak detection sensor of one of the computing devices, provide an output indicating the detection and the one of the computing devices.

A method of detecting a leak from a cooling structure and/or associated plumbing components of a computing device is also described herein. The computing device includes an apparatus that includes a plurality of leak detection sensors disposed in, or on external walls of, respective troughs of respective trays that are stacked on top of one another. The method involves receiving a signal from at least one leak detection sensor of the leak detection sensors indicating that the leak detection sensor has detected the liquid in a trough corresponding to the leak detection sensor. The method also involves determining a severity of the leak based on the at least one leak detection sensor and outputting an indication of the severity of the leak.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 illustrates an example of a computing device including a multi-severity leak detection apparatus.

FIG. 2 illustrates an example of the multi-severity leak detection apparatus along with a cooling structure of the computing device.

FIGS. 3A and 3B illustrate examples of configurations of leak detection sensors of the multi-severity leak detection apparatus.

FIG. 4 illustrates an example of drain lines from the multi-severity leak detection apparatus.

FIGS. 5A and 5B illustrate examples of a single trough with multiple leak-detection levels.

FIG. 6 illustrates an example of a system configured to implement multi-severity leak detection.

FIG. 7 illustrates an example method of multi-severity leak detection.

### DETAILED DESCRIPTION

### Overview

Many computing devices include cooling structures that transfer heat generated by electronic components within the computing devices to a liquid flowing through the cooling structures. Leaks within the cooling structures and associated components can damage the associated computing devices (and other computing devices nearby). When leaks occur within large collections of liquid-cooled computing devices (e.g., server farms), it can be difficult to identify severities of the leaks and prioritize them for mitigation.

For example, conventional techniques may merely identify that a leak exists, but not how severe it is. When multiple leaks within a collection of computing-devices occur, a technician may not be able to identify which one(s) is/are the most critical (and thus should be prioritized over other leaks).

Described herein is an apparatus for detecting a leak from a cooling structure and/or associated plumbing components that are installed within a computing device. The apparatus includes a first tray forming a first trough configured to surround a perimeter of the cooling structure. The first trough includes an interior wall with a plurality of portions configured to abut against the perimeter of the cooling structure and an exterior wall including a plurality of portions spaced apart from the portions of the interior wall. The apparatus also includes a first leak detection sensor that is configured to detect a liquid within the first trough or at one or more levels within the first trough and communicate the detection to the computing device or to a remote computing device.

The apparatus may provide multi-severity leak detection by detecting the liquid level at a plurality of levels in the first tray and/or by using at least one other tray collecting an overflow of the first tray and having another leak detection sensor. Depending upon a level within the first tray and/or which of the leak detection sensors have detected the liquid (e.g., which of the trays have the liquid within them), multiple severity levels may be identified. The multiple severity levels may be used to prioritize leaks in multi-computing device systems for efficient mitigation.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

### Example Computing Device

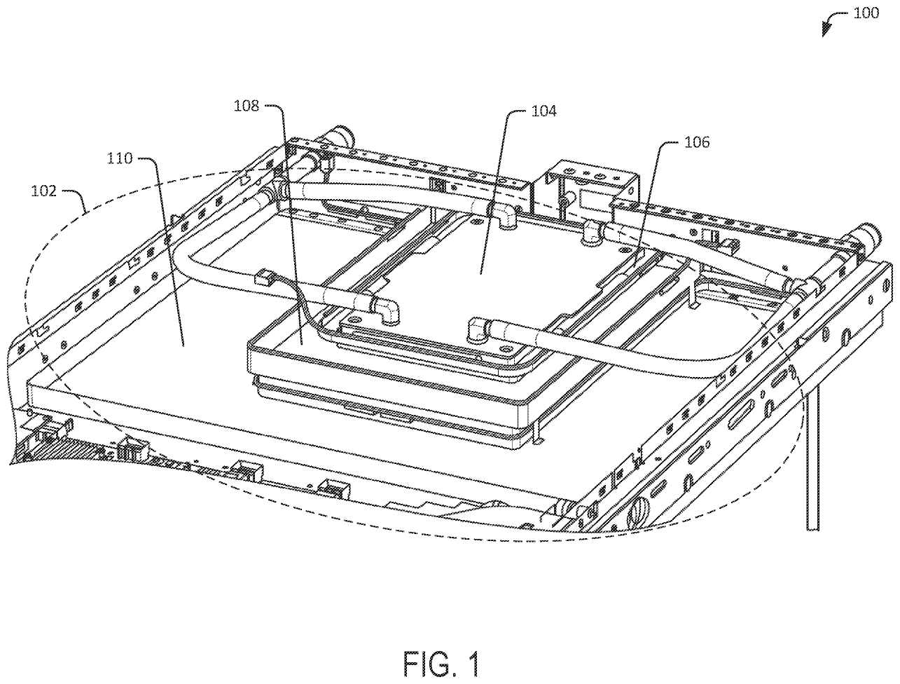

FIG. 1 illustrates an example of a computing device 100 with a leak detection apparatus 102. The computing device 100 includes a cooling structure 104 (e.g., cold plate) which may include associated plumbing componentry (fittings, tubing, etc.) configured to transfer heat out of the computing device 100 via a liquid (e.g., water or glycol).

At least a first tray 106 of the leak detection apparatus 102 surrounds the cooling structure 104 in a plan view (e.g., looking down at the cooling structure 104) such that leaks from the cooling structure 104 and/or connections to the cooling structure 104 may be captured by the first tray 106. In the illustrated example, a second tray 108 partially surrounds the first tray 106 in the plan view (e.g., on three sides), and a third tray 110 partially surrounds the second tray 108 in the plan view (e.g., on three sides). Portions of the trays may overlap in the plan view. In some implementations, the second tray 108 may fully surround the first tray 106 in the plan view and/or the third tray 110 may fully surround the second tray 108 in the plan view. The layout/configurations of the trays may be dependent upon where the cooling structure 104 is relative to the computing device 100.

The trays are organized such that an overflow of the first tray 106 flows into the second tray 108 and an overflow of the second tray 108 flows into the third tray 110. An overflow of the third tray 110 flows out of the computing device (e.g., to a drain). The second tray 108 may have a greater volume than the first tray 106 and the third tray 110 may have a greater volume than the second tray 108.

Within, or on, each of the trays is a respective leak detection sensor. Thus, liquid within the first tray 106 is detected by a first leak detection sensor that is on the first tray 106, liquid within the second tray 108 is detected by a second leak detection sensor that is on the second tray 108, and liquid within the third tray 110 is detected by a third leak detection sensor that is on the third tray 110. A severity of a leak may be determined by establishing which of the leak detection sensors detect the liquid. For example, if only the first leak detection sensor detects the liquid, then a severity of the leak may be low while if the first and second leak detection sensors detect the liquid, then a severity of the leak may be medium (e.g., increased severity relative to low severity). If all three of the leak detection sensors detect the liquid, then a severity of the leak may be high (e.g., further increased severity relative to medium severity). In most cases a leak will start at a low severity and then be escalated (e.g., to medium severity and then to high severity) as it continues to flow. In some cases, however, a leak may be in a component outside a footprint of the first tray, which may cause the leak to start at a medium or high severity.

The illustrated example shows a three-tray apparatus with each tray representing a severity level. More or less trays may be used without departing from the scope of this disclosure. For example, in some implementations, a single-tray apparatus may be used. In such implementations, multiple leak detection sensors or a single leak detection sensor that can detect multiple levels of the liquid may be used to detect the liquid at various levels within the single tray. The various levels may correspond to the low, medium, and high severities of leak detection.

### Example Apparatus

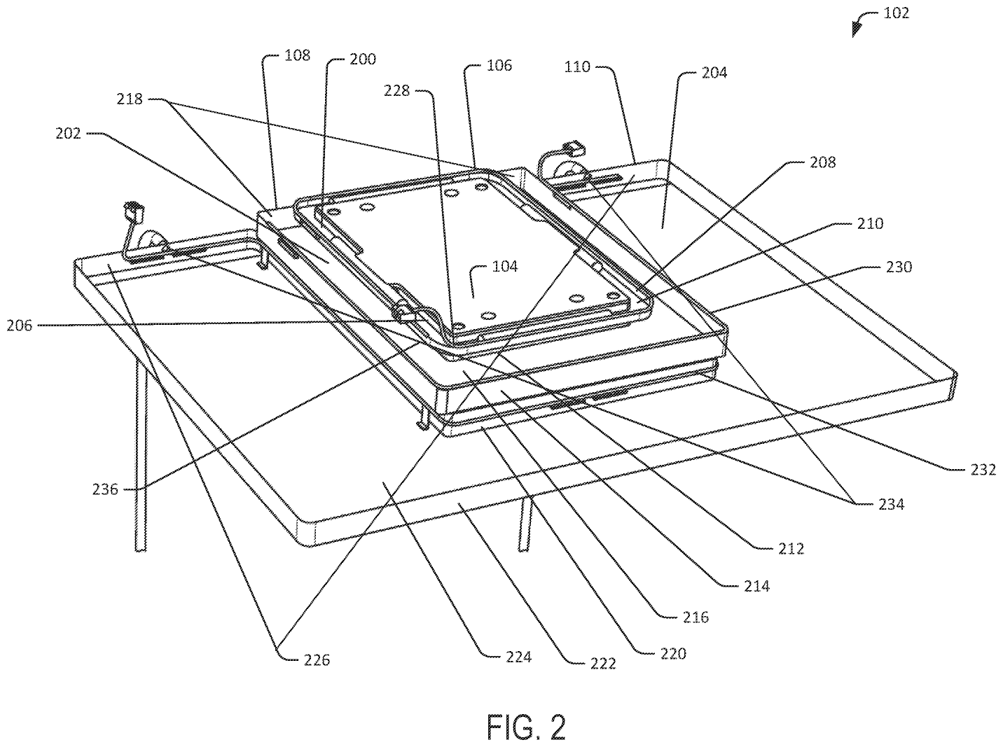

FIG. 2 illustrates an example of the leak detection apparatus 102 and the cooling structure 104. The leak detection apparatus 102 includes the first tray 106, the second tray 108, and the third tray 110. The first tray 106 forms a first trough 200 for capturing the liquid from the cooling structure 104 (and/or fittings of the cooling structure 104), the second tray 108 forms a second trough 202 for capturing the liquid after the first trough 200 is filled, and the third tray 110 forms a third trough 204 for capturing the liquid after the second trough 202 is filled.

The first trough 200 is configured to surround a perimeter of the cooling structure 104. To do so, the first trough 200 includes a first trough inner wall 206 that is generally vertical with a shape that corresponds to the perimeter of the cooling structure 104. For example, if the cooling structure 104 has a rectangular perimeter, the first trough inner wall 206 may include four portions corresponding to respective sides of the rectangle. The first trough inner wall 206 is configured to create a liquid-tight seal around the sides of the cooling structure 104 such that liquid dripping down the sides of the cooling structure 104 will fall into the first trough 200. Accordingly, a height of the first trough inner wall 206 may be below a seam, separation plane, or seal face of the cooling structure 104, such that, if the cooling structure 104 leaks from the seam, the first trough 200 may catch it.

Offset from the first trough inner wall 206 is a first trough outer wall 208 that is also generally vertical. The first trough outer wall 208 may have a similar perimeter shape as the first trough inner wall 206 (e.g., a rectangle). The first trough outer wall 208 may have a similar offset from the first trough inner wall 206 throughout (e.g., each portion of the first trough outer wall 208 may be equally offset from a corresponding portion of the first trough inner wall 206) or at least two portions of the first trough outer wall 208 may have different offsets from their respective corresponding portions of the first trough inner wall 206. A height of the first trough outer wall 208 may be similar or different than the height of the first trough inner wall 206.

The first trough inner wall 206 and the first trough outer wall 208 are connected by a first trough connecting portion 210. The first trough connecting portion 210 may form right angles to the first trough inner wall 206 and the first trough outer wall 208. Together, the first trough inner wall 206, the first trough connecting portion 210, and the first trough outer wall 208 form the first trough 200. In some implementations, the first trough inner wall 206 may not exist and the first trough connecting portion 210 may extend to interface with the cooling structure 104.

The second trough 202 is configured to surround at least a portion (e.g., one or more sides) of the first trough 200. As illustrated, the second trough 202 may be a u-shape trough that surrounds three sides of the first trough 200. In some implementations, the second trough 202 may completely surround the first trough 200 (e.g., be substantially adjacent to all sides of the first trough 200). In other implementation, the second trough 202 may only be adjacent to a single side of the first trough 200.

In the illustrated example, the second trough 202 includes a second trough inner wall 212, a second trough outer wall 214, and a second trough connecting portion 216. The second trough inner wall 212 and the second trough outer wall 214 are not complete loops (e.g., they are u-shaped). As such, second trough end walls 218 connect the second trough inner wall 212 to the second trough outer wall 214 at ends of the u-shape. The second trough end walls 218 may be parallel with a portion of the first trough outer wall 208 and be near or coincident with a plane formed by the portion of the first trough outer wall 208. Offsets between portions of the second trough inner wall 212 and the second trough outer wall 214 may be similar or different from one another. The second trough inner wall 212 may be within a perimeter of the first trough outer wall 208. This configuration may enable the second trough 202 to maximize an available storage volume.

The third trough 204 is configured to surround at least a portion (e.g., one or more sides) of the second trough 202. As illustrated, the third trough 204 may be a u-shape trough that surrounds three sides of the second trough 202. In some implementations, the third trough 204 may completely surround the second trough 202 (e.g., be substantially adjacent to all sides of the second trough 202). In other implementation, the third trough 204 may only be adjacent to a single side of the second trough 202.

In the illustrated example, the third trough 204 includes a third trough inner wall 220, a third trough outer wall 222, and a third trough connecting portion 224. The third trough inner wall 220 and the third trough outer wall 222 are not complete loops (e.g., they are u-shaped). As such, third trough end walls 226 connect the third trough inner wall 220 to the third trough outer wall 222 at ends of the u-shape. The third trough end walls 226 may be parallel with a portion of the first trough outer wall 208 and the second trough outer wall 214 and be near or coincident with a plane formed by the portion of the first trough outer wall 208 and/or the portion of the second trough outer wall 214. Offsets between portions of the third trough inner wall 220 and the third trough outer wall 222 may be similar or different from one another. The third trough inner wall 220 may be within a perimeter of the second trough outer wall 214. This configuration may enable the third trough 204 to maximize an available storage volume.

The configuration of the trays of the leak detection apparatus 102 may vary without departing from the scope of this disclosure. For example, while the second trough 202 and the third trough 204 are configured as u-shapes, they may be configured in any shape and/or size. The second trough 202 may only be adjacent to a single side of the first trough 200 and/or the third trough 204 may only be adjacent to a single side of the second trough 202. Furthermore, any number of trays may be used. The trays may be multiple pieces (e.g., stacked on one another as shown) or the trays may be formed as a single structure (formed as a single structure or adhered together to form a single structure).

The leak detection apparatus 102 also includes a first leak detection sensor 228, a second leak detection sensor 230, and a third leak detection sensor 232 disposed on respective trays. The leak detection sensors are configured to detect a liquid within associated troughs and/or various levels of the liquid within the associated troughs. For example, the leak detection sensors may be leak detection ropes or conductivity sensors and may include associated wires and/or connectors for communication with the computing device 100 and/or a remote computing device. The leak detection ropes may be 4-wire cables (e.g., two continuity wires and two sensing wires) that work on capacitance changes in the presence of the liquid. The conductivity sensors may be spot detectors with a pair of probes configured to contact the liquid in the respective areas (e.g., the troughs and/or spillways). Other types of leak detection sensors may be used without departing from the scope of this disclosure.

The leak detection sensors are configured to indicate, to the computing device 100 and/or the remote computing device, the associated liquid detections. A severity of the leak may be determined based on which of the leak detection sensors indicate the liquid. For example, if only the first leak detection sensor 228 indicates a presence of the liquid, then the leak may be considered low severity. If, however, the first leak detection sensor 228 and the second leak detection sensor 230 indicate a presence of the liquid, then the leak may be considered medium severity. Further, if the first leak detection sensor 228, the second leak detection sensor 230, and the third leak detection sensor 232 indicate a presence of the liquid, then the leak may be considered high severity. It should be noted that, in many cases, a leak will start with a low severity and continue to flow, if unmitigated, to have its severity increased. Thus, if a leak reaches a second trigger (e.g., the second leak detection sensor 230 or a second level within a single-tray apparatus), the leak may have an increased severity (e.g., go from low to medium). Similarly, if the leak reaches a third trigger (e.g., the third leak detection sensor 232 or a third level within a single-tray apparatus), the leak may have a further increased severity (e.g., go from medium to high).

If a single tray is implemented, the leak detection apparatus 102 may only include a single leak detection sensor that can indicate the liquid at various levels within the single tray. In this way, multiple severity levels may be generated using a single tray (e.g., corresponding to various levels within the tray).

The first leak detection sensor 228 may be disposed on top of the first trough outer wall 208. As such, the first leak detection sensor 228 may be configured to detect the liquid when it reaches a top of the first trough 200. The second leak detection sensor 230 may be disposed on top of the second trough outer wall 214. As such, the second leak detection sensor 230 may be configured to detect the liquid when it reaches a top of the second trough 202. The third leak detection sensor 232 may be disposed within the third trough 204 along the third trough inner wall 220, the third trough outer wall 222, and/or the third trough end walls 226. The third leak detection sensor 232 may be disposed at a height that corresponds to drain holes 234 of the third tray 110. As such, the third leak detection sensor 232 may be configured to detect the liquid when it reaches the drain holes 234.

In some implementations, a hygroscopic material 236 may be disposed within one or more of the troughs. The hygroscopic material 236 is configured to absorb the liquid and may slow a rate of filling the associated trough.

### Example Leak Detection Sensor Configurations

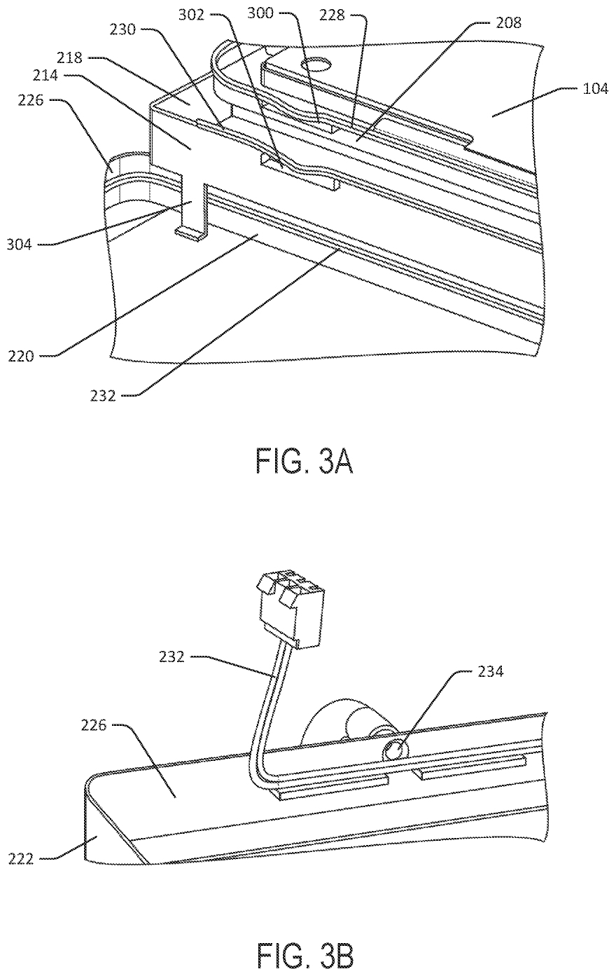

FIGS. 3A and 3B illustrate example configurations of the leak detection sensors. FIG. 3A illustrates examples of portions of the first leak detection sensor 228, the second leak detection sensor 230, and the third leak detection sensor 232. FIG. 3B illustrates an example of a portion of the third leak detection sensor 232.

The first tray 106 may include a first spillway 300 (or drain hole) formed within the first trough outer wall 208. The first spillway 300 may be any structure (e.g., lip, trough, valley, hole, chute, depression, or gutter) that communicates with the first trough 200 and is configured to allow for fluid to drain from the first trough 200 into the second trough 202. The second tray 108 may include a second spillway 302 (or drain hole) formed within the second trough outer wall 214. The second spillway 302 may be configured to communicate with the second trough 202 and allow for fluid to drain from the second trough 202 into the third trough 204.

The first leak detection sensor 228 may be at least partially disposed within the first spillway 300. For example, the first leak detection sensor 228 may be disposed on top of the first trough outer wall 208 and dip into the first spillway 300. As such, the first leak detection sensor 228 may detect the fluid as it reaches/flows through the first spillway 300. Alternatively or in addition, the first leak detection sensor may detect the fluid as it reaches/flows over the first trough outer wall 208.

In some implementations, the first leak detection sensor 228 may be configured to only detect fluid in the first spillway 300 (instead of in addition to fluid going over the first trough outer wall 208). In such implementations, the first leak detection sensor 228 may be a short portion of a leak detection rope or a conductive sensor disposed within the first spillway 300. Furthermore, the first leak detection sensor 228 may be disposed on the first trough connecting portion 210 such that the first leak detection sensor 228 can detect the liquid as it enters the first trough 200 (instead of after it fills the first trough 200). Similarly, the first leak detection sensor 228 may be disposed on the first trough inner wall 206 and/or the first trough outer wall 208 at a height between the first trough connecting portion 210 and a top of the first trough inner wall 206 or the first trough outer wall 208. The location and configuration of the first leak detection sensor 228 relative to the first trough 200 may vary without departing from the scope of this disclosure.

The second leak detection sensor 230 may be at least partially disposed within the second spillway 302. For example, the second leak detection sensor 230 may be disposed on top of the second trough outer wall 214 and dip into the second spillway 302. As such, the second leak detection sensor 230 may detect the fluid as it reaches/flows through the second spillway 302 and/or as it reaches/flows over the second trough outer wall 214.

In some implementations, the second leak detection sensor 230 may be configured to only detect fluid in the second spillway 302 (instead of in addition to fluid going over the second trough outer wall 214). In such implementations, the second leak detection sensor 230 may be a short portion of leak detection rope or a conductive sensor disposed within the second spillway 302. Furthermore, the second leak detection sensor 230 may be disposed on the second trough connecting portion 216 such that the second leak detection sensor 230 can detect the liquid as it enters the second trough 202 (instead of after it fills the second trough 202). Similarly, the second leak detection sensor 230 may be disposed on the second trough inner wall 212 and/or the second trough outer wall 214 at a height between the second trough connecting portion 216 and a top of the second trough inner wall 212 or the second trough outer wall 214. The location and configuration of the second leak detection sensor 230 relative to the second trough 202 may vary without departing from the scope of this disclosure.

The second tray 108 may be supported above the third tray 110 via legs 304 attached to the second tray 108. For example, the legs 304 may extend from a bottom of the second trough outer wall 214. The legs 304 may support the second tray 108 and also the first tray 106 that is supported by the second tray 108.

The third leak detection sensor 232 may be disposed along the third trough inner wall 220, the third trough outer wall 222, and/or the third trough end walls 226. For example, the third leak detection sensor 232 may be at least partially disposed proximate the drain holes 234. As such, the third leak detection sensor 232 may detect the fluid as it reaches/flows through the drain holes 234.

In some implementations, the third leak detection sensor 232 may be configured to only detect fluid near the drain holes 234 (instead of in addition to other portions of the third trough 204). In such implementations, the third leak detection sensor 232 may be a short portion of leak detection rope or a conductive sensor disposed in front of at least one of the drain holes 234. Furthermore, the third leak detection sensor 232 may be disposed on the third trough connecting portion 224 such that the third leak detection sensor 232 can detect the liquid as it enters the third trough 204 (instead of after it fills the third trough 204). Similarly, the third leak detection sensor 232 may be disposed on the third trough inner wall 220 and/or the third trough outer wall 222 at a height between the third trough connecting portion 224 and a top of the third trough inner wall 220 or the third trough outer wall 222. The location and configuration of the third leak detection sensor 232 relative to the third trough 204 may vary without departing from the scope of this disclosure.

Although the leak detection sensors are illustrated as leak detection ropes, the leak detection sensors may be any device capable of detecting when the liquid is present at the above-described positions in the respective troughs. For example, any of the leak detection sensors may be conductive sensors, capacitive sensors, optical sensors, float sensors, depth sensors, or distance sensors.

### Example Drain Lines

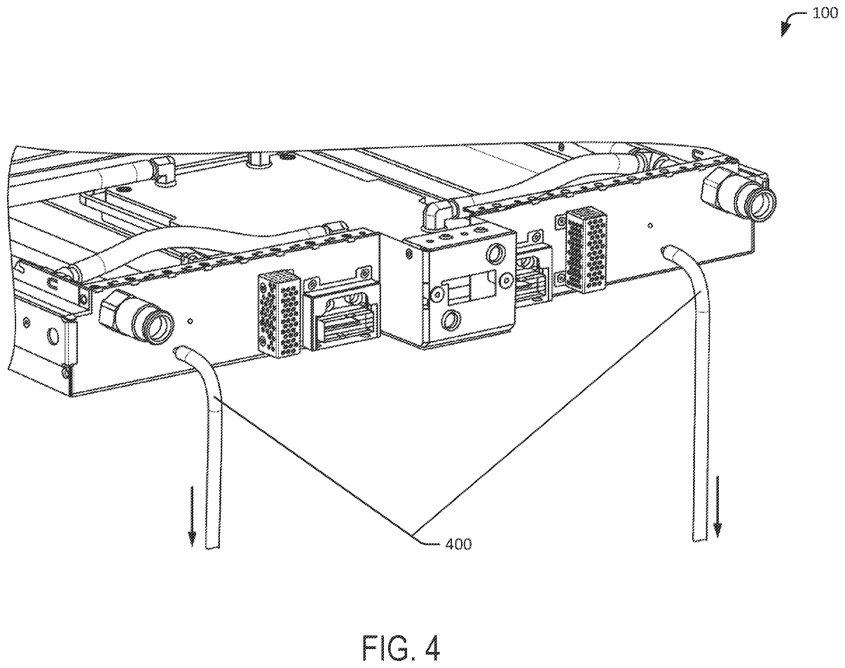

FIG. 4 illustrates an example of drain lines 400 connected to the leak detection apparatus 102. The drain lines 400 may be connected to the drain holes 234 such that, when the third trough 204 fills to a height of the drain holes 234, the fluid may be drained away from the computing device 100 as opposed to overflowing into the computing device 100. The drain lines 400 may be connected to the drain holes 234 via any applicable connectors (e.g., bulkheads, tubing fittings, or grommets).

Although the drain holes 234 have been described as being formed by the third tray 110, in an implementation where there is only a single tray (instead of three), the drain holes 234 may be formed by the single tray (e.g., the first tray 106). Similarly, in an implementation where there are two trays, the drain holes 234 may be formed by the second tray 108, or, in an implementation where there are four trays, the drain holes 234 may be formed by the fourth tray.

The drain lines 400 may extend to a bottom of a server rack or tower or join a bus that connects drains from a plurality of computing devices within the server rack or tower. Furthermore, multiple server racks or towers may have their respective drains connected to facilitate liquid capture from leaking components.

### Example Single-Tray Configurations

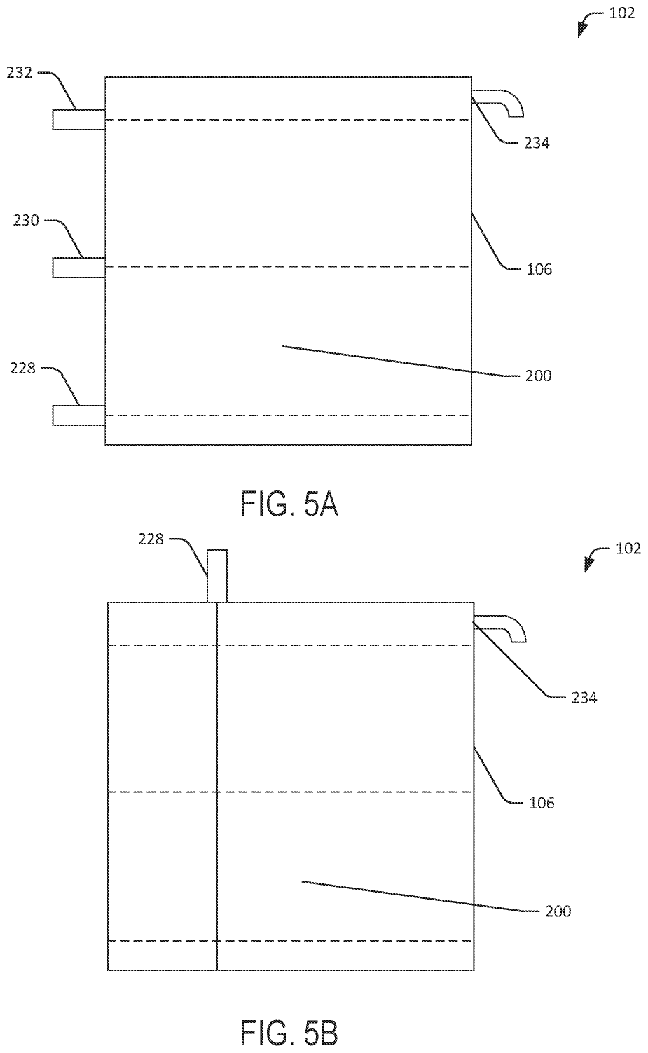

FIGS. 5A and 5B illustrate examples of single-tray configurations of the leak detection apparatus 102. FIG. 5A illustrates an example of a single-tray configuration using three leak detection sensors (e.g., the first leak detection sensor 228, the second leak detection sensor 230, and the third leak detection sensor 232). FIG. 5B illustrates an example of a single-tray configuration using a single leak detection sensor (e.g., the first leak detection sensor 228). The single-tray is referred to as the first tray 106 as it is still configured to surround the cooling structure 104.

FIG. 5A illustrates a single tray (e.g., the first tray 106) with a single trough (e.g., the first trough 200) and the drain holes 234 formed by the single tray. The first leak detection sensor 228 may be configured to detect the liquid at a first level within the first trough 200, the second leak detection sensor 230 may be configured to detect the liquid at a second level within the first trough 200 that is higher than the first level, and the third leak detection sensor 323 may be configured to detect the liquid at a third level within the first trough 200 that is higher than the second level. There may be more or less leak detection sensors and/or more or less levels without departing from the scope of this disclosure. Furthermore, the leak detection sensors may be disposed at any heights within the first trough 200.

FIG. 5B illustrates a single tray (e.g., the first tray 106) with a single trough (e.g., the first trough 200) and the drain holes 234 formed by the single tray. Different from the implementation shown in FIG. 5A, however, is that a single leak detection sensor is utilized (e.g., the first leak detection sensor 228). In the illustrated implementation, the first leak detection sensor 228 is configured to detect a plurality of levels of the liquid within the first trough 200. For example, the first leak detection sensor 228 may be a coil of leak detection rope that climbs the first trough 200, a depth or distance sensor, a float sensor, or a single device with a linear array of sensors. Regardless of how it is configured, the first leak detection sensor 228 is configured to provide various outputs corresponding to respective levels of the liquid within the first trough 200.

In this way, a single tray may be used while still providing multiple signals usable to determine a severity of a leak. It should be noted that, regardless of whether a single tray or a multi-tray configuration is implemented, the end result is similar. That is, depending upon a volume of the liquid that has entered the leak detection apparatus 102, different leak detection signals may be generated.

### Example System

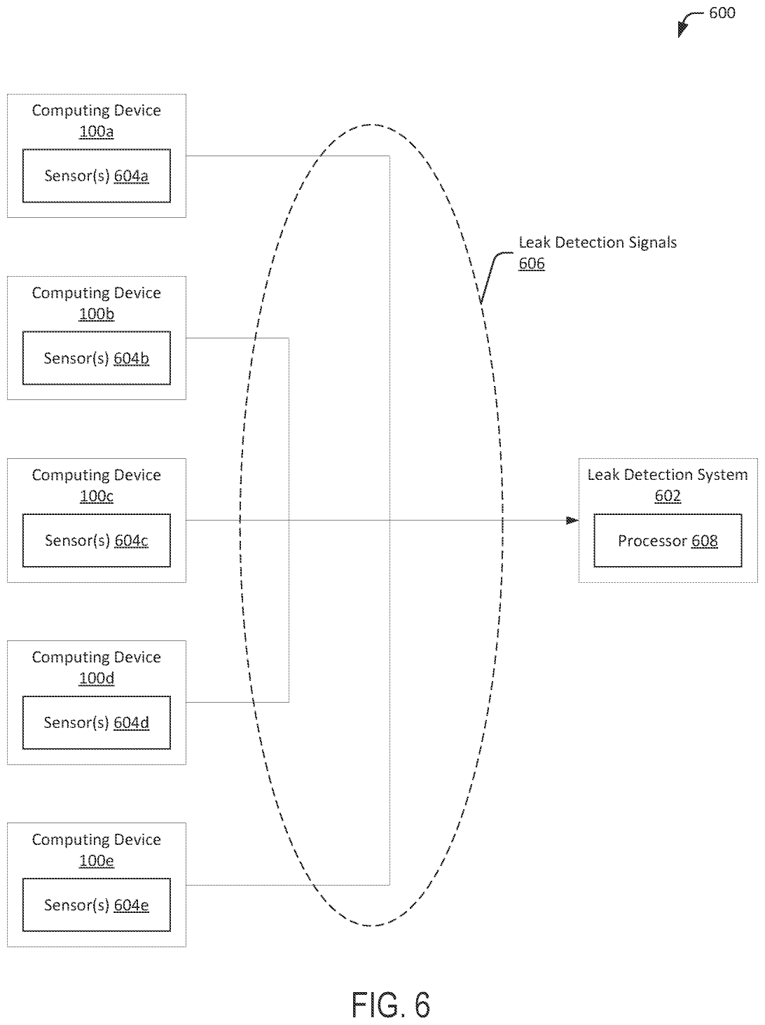

FIG. 6 illustrates an example of a system 600 configured to implement multi-severity leak detection. The system 600 includes a plurality of computing devices 100 (e.g., computing devices 100a-100e) that are communicatively coupled with a leak detection system 602. Each of the computing devices 100 includes a cooling structure 104 and a leak detection apparatus 102 with one or more sensor(s) 604 (e.g., sensors 604a-604e). The sensor(s) 604 may be one or more leak detection sensors such as the first leak detection sensor 228 configured to detect multiple liquid levels or a combination of multiple leak detection sensors (e.g., the first leak detection sensor 228, the second leak detection sensor 230, and the third leak detection sensor 232).

Regardless of how the each of the leak detection apparatuses 102 are configured in the system 600 (they may be similar or different from one another), each computing device 100 is configured to generate leak detection signals 606 for receipt by the leak detection system 602. The leak detection signals 606 are usable by the leak detection system 602 to determine a severity of each of the leaks within the system 600.

The leak detection signals 606 may be discrete (e.g., indicating that liquid does exist or does not exist for each of multiple sensors 604 within a computing device 100 and/or at the liquid is at a single level) or analog (e.g., indicating a liquid level within a computing device 100). The leak detection signals 606 may come directly from the sensor(s) 604, routed through one or more hubs, be generated by the respective computing devices 100 (e.g., the sensors 604 are connected to their respective computing devices 100), or some combination thereof. The leak detection signals 606 indicate an amount of the liquid within one or more trays within each of the computing devices 100.

The leak detection system 602 includes a processor 608 configured to (e.g., execute instructions stored on non-transitory media causing the processor 608 to) determine severities of the leaks based upon the leak detection signals 606. For example, if the leak detection system 602 receives a leak detection signal 606 from computing device 100a that indicates that the liquid is at a first volume within computing device 100a (e.g., detected by the first leak detection sensor 228 of computing device 100a or detected at a first level by the first leak detection sensor 228 of computing device 100a) then the leak detection system 602 may determine that computing device 100a has a low severity leak. If the leak detection system 602 receives a leak detection signal 606 from computing device 100b that indicates that the liquid is at a second volume within computing device 100b that is higher than the first volume (e.g., detected by the first leak detection sensor 228 and the second leak detection sensor 230 of computing device 100b or detected at a second level by the first leak detection sensor 228 of computing device 100b) then the leak detection system 602 may determine that computing device 100b has a medium severity leak. If the leak detection system 602 receives a leak detection signal 606 from computing device 100c that indicates that the liquid is at a third volume within computing device 100b that is higher than the second volume (e.g., detected by the first leak detection sensor 228, the second leak detection sensor 230, and the third leak detection sensor 232 of computing device 100c or detected at a third level by the first leak detection sensor 228 of computing device 100c) then the leak detection system 602 may determine that computing device 100c has a high severity leak. Accordingly, the leak detection system 602 may output a list of prioritized leaks (e.g., high severity leak in computing device 100c, medium severity leak in computing device 100b, and low severity leak in computing device 100a). In this way, the leak detection system 602 can be used to prioritize the leaks within the system 600. It should be noted that as a leak transitions from a low to medium severity or from a medium to high severity, the output may be updated or further updated based on the transitions.

In some implementations, the leak detection system 602 may reside/be implemented within one of the computing devices 100. For example, one of the computing devices 100 may have an input for the sensors 604 or an intermediate device. Thus, a separate computing device may not be needed to implement the leak detection system 602.

Furthermore, the sensors 604 of a computing device 100 may be communicatively coupled to the respective computing device 100. In other words, the sensors 604 may not be coupled with the leak detection system 602. In such implementations, each computing device 100 may track severities of its own leaks and communicate the leaks to the leak detection system 602 (either a separate computing device or one of the computing devices 100) via a network.

### Example Method

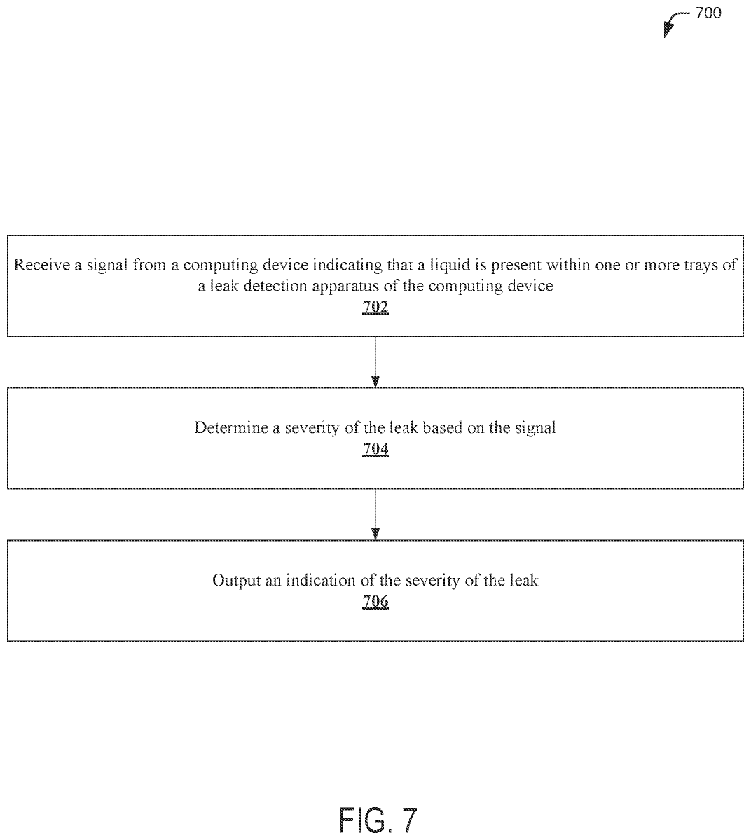

FIG. 7 illustrates an example of a method 700 of multi-severity leak detection. Steps may be combined, divided, and/or omitted without departing from the scope of this disclosure.

At 702, a signal is received from a computing device indicating that a liquid is present within one or more trays of a leak detection apparatus of the computing device. The signal may indicate a level of the liquid within a single trough of the computing device or indicate an existence of the liquid within one or more of a plurality of troughs of the computing device. For example, the leak detection system 602 may receive a leak detection signal 606 from a computing device 100. The leak detection signal 606 may come directly from the sensor(s) 604 of the computing device 100 or from a processor of the computing device 100.

At 704, a severity of the leak is determined based on the signal. For example, if the leak detection signal 606 indicates that the liquid is at a first volume within the computing device 100 (e.g., detected by the first leak detection sensor 228 of computing device 100 or detected at a first level by the first leak detection sensor 228 of computing device 100) then the leak detection system 602 may determine that computing device 100 has a low severity leak. If the leak detection signal 606 indicates that the liquid is at a second volume within the computing device 100 that is higher than the first volume (e.g., detected by the first leak detection sensor 228 and the second leak detection sensor 230 of the computing device 100 or detected at a second level by the first leak detection sensor 228 of the computing device 100) then the leak detection system 602 may determine that the computing device 100 has a medium severity leak. If the leak detection signal 606 indicates that the liquid is at a third volume within the computing device 100 that is higher than the second volume (e.g., detected by the first leak detection sensor 228, the second leak detection sensor 230, and the third leak detection sensor 232 of the computing device 100 or detected at a third level by the first leak detection sensor 228 of the computing device 100) then the leak detection system 602 may determine that computing device 100 has a high severity leak. More or less severity levels may be used without departing from the scope of this disclosure.

At 706, an indication of the severity of the leak is output. For example, the leak detection system 602 may output an indication of the leak along with an identifier of the computing device 100 and a severity of the leak. In this way, the indication provides more information than simply indicating a leak exists. Accordingly, when multiple computing devices are connected to the leak detection system 602, leaks may be prioritized for mitigation based on the severity levels.

### EXAMPLES

Example 1: An apparatus for detecting a leak from a cooling structure and/or associated plumbing components that are installed within a computing device, the apparatus comprising: a first tray forming a first trough, the first trough: configured to surround a perimeter of the cooling structure; and including: an interior wall with a plurality of portions configured to abut against the perimeter of the cooling structure; and an exterior wall including a plurality of portions spaced apart from the portions of the interior wall; and a first leak detection sensor disposed within the first trough or on top of the interior wall or the exterior wall of the first trough, the first leak detection sensor: configured to detect a liquid within the first trough or at one or more levels within the first trough; and communicate the detection of the liquid in the first trough to the computing device or another computing device.

Example 2: The apparatus of example 1, wherein the first leak detection sensor is configured to: detect the liquid at a plurality of levels within the first trough; and communicate the levels to the computing device or the other computing device.

Example 3: The apparatus of example 1 or 2, wherein the first leak detection sensor includes a conductive sensor.

Example 4: The apparatus of example 3, wherein the conductive sensor includes a rope.

Example 5: The apparatus of any preceding example, wherein the first tray includes a hygroscopic material disposed within the first trough.

Example 6: The apparatus of any preceding example, wherein a top of the interior wall is at or below a separation plane of the cooling structure.

Example 7: The apparatus of any preceding example, wherein: the apparatus includes: a second tray disposed underneath the first tray, the second tray forming a second trough that at least partially surrounds the first trough; and a second leak detection sensor disposed within the second trough or on top of an exterior wall of the second trough, the second leak detection sensor: configured to detect the liquid within the second trough or at a level within the second trough; and communicate a detection of the liquid in the second trough to the computing device or another computing device; wherein the first tray forms a first spillway that communicates with the first trough; and wherein the first spillway is configured to cause the liquid to drain from the first trough into the second trough.

Example 8: The apparatus of example 7, wherein the second trough is adjacent to at least three sides of the first trough.

Example 9: The apparatus of example 7 or 8, wherein the first leak detection sensor is configured to detect the liquid when it reaches a level of the first spillway.

Example 10: The apparatus of example 7, 8, or 9, wherein: the apparatus includes: a third tray disposed underneath the second tray, the third tray forming a third trough that at least partially surrounds the second trough; and a third leak detection sensor disposed within the third trough, the third leak detection sensor: configured to detect the liquid within the third trough or at a level within the third trough; and communicate the detection of the liquid in the third trough to the computing device or another computing device; wherein the second tray forms a second spillway that communicates with the second trough; and wherein the second spillway is configured to cause the liquid to drain from the second trough into the third trough.

Example 11: The apparatus of example 10, wherein the second leak detection sensor is configured to detect the liquid when it reaches a level of the second spillway.

Example 12: The apparatus of example 10 or 11, wherein: the second trough has a volume that is greater than the first trough; and the third trough has a volume that is greater than the second trough.

Example 13: The apparatus of example 10, 11, or 12, wherein the third trough is adjacent to at least three sides of the second trough.

Example 14: The apparatus of example 10, 11, 12, or 13, wherein the third tray forms one or more drain holes configured to cause the liquid to drain from the third trough out of the computing device.

Example 15: The apparatus of example 14, wherein the third leak detection sensor is configured to detect the liquid when it reaches the drain holes.

Example 16: A system comprising: a plurality of computing devices, each of the computing devices including: a cooling structure attached to one or more electronic components; and an apparatus for detecting a leak from the cooling structure and/or one or more plumbing components associated with the cooling structure that are installed in the respective computing device, the apparatus including: a first tray forming a first trough, the first trough: configured to surround a perimeter of the cooling structure; and including: an interior wall with a plurality of portions configured to abut against the perimeter of the cooling structure; and an exterior wall including a plurality of portions spaced apart from the portions of the interior wall; and a first leak detection sensor disposed within the first trough or on top of the interior wall or the exterior wall of the first trough, the first leak detection sensor configured to: detect a liquid within the first trough or at one or more levels within the first trough; and communicate the detection of the liquid in the first trough to the respective computing device or outside of the respective computing device; and a processor remote to the computing devices, the processor configured to: receive indications of detections of the liquid by the first leak detection sensors of the computing devices from the computing devices or the first leak detection sensors of the computing devices; and responsive to receiving an indication of a detection of the liquid by a first leak detection sensor of one of the computing devices from the one of the computing devices or the first leak detection sensor of the one of the computing devices, provide an output indicating the detection and the one of the computing devices.

Example 17: The system of example 16, wherein: the apparatus includes: a second tray disposed underneath the first tray, the second tray forming a second trough that at least partially surrounds the first trough; and a second leak detection sensor disposed within the second trough or on top of an exterior wall of the second trough, the second leak detection sensor: configured to detect the liquid within the second trough or at a level within the second trough; and communicate a detection of the liquid in the second trough to the respective computing device or outside of the respective computing device; the first tray forms a first spillway that communicates with the first trough; the first spillway or drain hole is configured to cause the liquid to drain from the first trough into the second trough; and the processor is configured to: receive indications of detections of the liquid by the second leak detection sensors from the computing devices or the second leak detection sensors of the computing devices; responsive to receiving a detection of the liquid from a second leak detection sensor of the one of the computing devices, increase a severity level of the detection; and update the output indicating the increased severity of the detection.

Example 18: The system of example 17, wherein: the apparatus includes: a third tray disposed underneath the second tray, the third tray forming a third trough that at least partially surrounds the second trough; and a third leak detection sensor disposed within the third trough, the third leak detection sensor: configured to detect the liquid within the third trough or at a level within the third trough; and communicate the detection of the liquid in the third trough to the respective computing device or outside of the respective computing device; the second tray forms a second spillway that communicates with the second trough; the second spillway or drain hole is configured to cause the liquid to drain from the second trough into the third trough; and the processor is configured to: receive indications of detections of the liquid by the third leak detection sensors of the computing devices from the computing devices or the third leak detection sensors of the computing devices; responsive to receiving an indication of a detection of the liquid by a third leak detection sensor of the one of the computing devices from the one of the computing devices or the third leak detection sensor of the one of the computing devices, further increase the severity level of the detection; and further update the output indicating the further increased severity of the detection.

Example 19: The system of example 18, wherein the third leak detection sensor is configured to detect the liquid when it reaches one or more drain holes configured to cause the liquid to drain from the third trough out of the respective computing device.

Example 20: A method of detecting a leak of a liquid from a cooling structure and/or associated plumbing components of a computing device, the computing device including an apparatus that includes a plurality of leak detection sensors disposed in, or on external walls of, respective troughs of respective trays that are stacked on top of one another, the method performed by a remote computing device, the method comprising: receiving a signal from at least one leak detection sensor of the leak detection sensors indicating that the leak detection sensor has detected the liquid in a trough corresponding to the leak detection sensor; determining a severity of the leak based on the at least one leak detection sensor; and outputting an indication of the severity of the leak.

### CONCLUSION

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terms up, upper, down, lower, above, below, left, right, forward, rearward, and the like are intended to be understood in the context of the representations described and illustrated above so that a wearable device may have such an orientation in reference to the frame or to various elements as supported by the frame or as illustrated in the drawing figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description, but is not intended to be exhaustive or limited to this disclosure in the form disclosed. Many modifications and variations will be apparent to those of ordinary skill in the art without departing from the scope and spirit of this disclosure. The various embodiments were chosen and described in order to best explain the principles of this disclosure and the practical application, and to enable others of ordinary skill in the art to understand this disclosure for various embodiments with various modifications as are suited to the particular use contemplated.

What is claimed is:

1. An apparatus for detecting a leak of a liquid from a cooling structure installed within a computing device, the apparatus comprising:
a first tray:
configured to receive the cooling structure; and
forming a first trough configured to capture the liquid as it leaks from the cooling structure; and
a first leak detection sensor disposed on the first tray, the first leak detection sensor configured to:
detect the liquid at one or more levels within the first trough; and
communicate the detection of the liquid in the first trough to the computing device or another computing device.

2. The apparatus of claim 1, further including:
a second tray forming a second trough configured to capture the liquid as it overflows the first trough; and
a second leak detection sensor disposed on the second tray, the second leak detection sensor configured to:
detect the liquid at a level within the second trough; and
communicate a detection of the liquid in the second trough to the computing device or another computing device.

3. The apparatus of claim 2, wherein the first leak detection sensor is configured to detect the liquid at a single level within the first trough.

4. The apparatus of claim 3, wherein:
the first tray forms a first spillway that communicates with the first trough; and
the single level within the first trough corresponds to a level of the first spillway.

5. The apparatus of claim 2, wherein the second trough is substantially adjacent to at least three sides of the first trough in a plan view.

6. The apparatus of claim 2, further including:
a third tray forming a third trough configured to capture the liquid as it overflows the second trough; and
a third leak detection sensor disposed on the third tray, the third leak detection sensor configured to:
detect the liquid at a level within the third trough; and
communicate a detection of the liquid in the third trough to the computing device or another computing device.

7. The apparatus of claim 6, wherein:
the second tray forms a second spillway that communicates with the second trough; and
the level within the second trough corresponds to a level of the second spillway.

8. The apparatus of claim 6, wherein:
the second trough has a volume that is greater than the first trough; and
the third trough has a volume that is greater than the second trough.

9. The apparatus of claim 6, wherein the third trough is substantially adjacent to at least three sides of the second trough in a plan view.

10. The apparatus of claim 6, wherein the third tray forms one or more drain holes configured to allow the liquid to drain from the third trough out of the computing device.

11. The apparatus of claim 10, wherein the level within the third trough corresponds to a level of the drain holes.

12. The apparatus of claim 1, wherein the first leak detection sensor is further configured to:
detect the liquid at a plurality of levels within the first trough; and
communicate the levels to the computing device or the other computing device.

13. The apparatus of claim 1, wherein:
the first leak detection sensor is configured to detect the liquid at a single level within the first trough; and
the apparatus contains a second leak detection sensor disposed on the first tray, the second leak detection sensor configured to:
detect the liquid at another level within the first trough that is different from the single level within the first trough; and
communicate the detection of the liquid at the other level in the first trough to the computing device or another computing device.

14. The apparatus of claim 1, wherein the first tray includes a hygroscopic material disposed within the first trough.

15. The apparatus of claim 1, wherein:
the first tray forms an interior wall of the first trough; and
a height of the interior wall of the first trough is at or below a separation plane of the cooling structure.

16. A system comprising:
a plurality of computing devices, each of the computing devices including:
a cooling structure attached to one or more electronic components; and
an apparatus for detecting a leak of a liquid from the respective cooling structure, the apparatus comprising:
a first tray:
surrounding the respective cooling structure; and
forming a first trough configured to capture the liquid as it leaks from the respective cooling structure; and
a first leak detection sensor disposed on the respective first tray, the respective first leak detection sensor configured to:
detect the liquid at one or more levels within the respective first trough; and
communicate the detection of the liquid in the respective first trough to the respective computing device or another computing device;
a processor remote to the computing devices, the processor configured to:
receive indications of detections of the liquid by the first leak detection sensors of the computing devices from the computing devices or the first leak detection sensors of the computing devices; and
responsive to receiving an indication of a detection of the liquid by a first leak detection sensor of one of the computing devices from the one of the computing devices or the first leak detection sensor of the one of the computing devices, provide an output indicating the detection and the one of the computing devices.

17. The system of claim 16, wherein:
the apparatus includes:
a second tray forming a second trough configured to capture the liquid as it overflows from the respective first trough; and
a second leak detection sensor disposed on the respective second tray, the respective second leak detection sensor configured to:
detect the liquid at a level within the respective second trough; and
communicate the detection of the liquid in the respective second trough to the respective computing device or the other computing device; and
the processor is configured to:
receive indications of detections of the liquid by the second leak detection sensors from the computing devices or the second leak detection sensors of the computing devices; and
responsive to receiving a detection of the liquid from a second leak detection sensor of the one of the computing devices:
increase a severity level of the detection; and
update the output to indicate the increased severity of the detection.

18. The system of claim 17, wherein:
the apparatus includes:
a third tray forming a third trough configured to capture the liquid as it overflows from the respective second trough; and
a third leak detection sensor disposed on the respective third tray, the respective third leak detection sensor configured to:
detect the liquid at a level within the respective third trough; and
communicate the detection of the liquid in the respective third trough to the respective computing device or the other computing device; and
the processor is configured to:
receive indications of detections of the liquid by the third leak detection sensors from the computing devices or the third leak detection sensors of the computing devices; and
responsive to receiving a detection of the liquid from a third leak detection sensor of the one of the computing devices:
further increase the severity level of the detection; and
further update the output to indicate the further increased severity of the detection.

19. The system of claim 18, wherein:
the respective first leak detection sensor is configured to detect the liquid when it reaches a first spillway between the respective first trough and the respective second trough;
the respective second leak detection sensor is configured to detect the liquid when it reaches a second spillway between the respective second trough and the respective third trough; and
the respective third leak detection sensor is configured to detect the liquid when it reaches one or more drain holes between the respective third trough and a drain.

20. A method of detecting a leak of a liquid from a cooling structure of a computing device, the computing device including an apparatus that includes a plurality of leak detection sensors disposed on respective trays, the method performed by a remote computing device, the method comprising:
receiving a signal indicating that a leak detection sensor of the leak detection sensors has detected the liquid in a trough corresponding to the leak detection sensor;
determining a severity of the leak based on an identification of the leak detection sensor; and
outputting an indication of the severity of the leak.
